(19) United States
(12) Patent Application Publication
(10) Pub. No.: US 2024/0213323 A1
(43) Pub. Date: Jun. 27, 2024

(54) SINGLE-TRANSISTOR STRUCTURE, MULTI-TRANSISTOR STRUCTURE, AND ELECTRONIC APPARATUS

(71) Applicant: NINGBO INSTITUTE OF MATERIALS TECHNOLOGY AND ENGINEERING, CHINESE ACADEMY OF SCIENCES, Ningbo, Zhejiang (CN)

(72) Inventor: Mingzhi DAI, Ningbo, Zhejiang (CN)

(73) Assignee: NINGBO INSTITUTE OF MATERIALS TECHNOLOGY AND ENGINEERING, CHINESE ACADEMY OF SCIENCES, Ningbo, Zhejiang (CN)

(21) Appl. No.: 18/555,871

(22) PCT Filed: Feb. 8, 2022
(86) PCT No.: PCT/CN2022/075442

§ 371 Date: Oct. 18, 2023

(30) Foreign Application Priority Data
Apr. 19, 2021 (CN) 202110418615.6

(51) Int. Cl. H01L 29/10; H01L 29/423; H01L 29/78

(52) U.S. Cl. CPC H01L 29/1033; H01L 29/42376; H01L 29/785

(57) ABSTRACT

A single-transistor structure, a multi-transistor structure, and an electronic device. The single-transistor structure includes: a substrate; a channel, a source, and a drain, which are located at a same side of the substrate, where the channel has a first end and a second end opposite to each other along an extension direction, the source and the drain are in electrical contact with the first end and the second end, respectively; a gate disposed between the source and the drain, where the gate covers a part of the channel, and an insulating layer is sandwiched between the channel and the gate; and a channel electrode in electrical contact with another part of the channel which is exposed from the gate, the channel electrode and the part of the channel wrapped by the gate overlap partially along the extension direction, and the channel electrode is isolated and insulated from the gate.

### FIELD

The present disclosure relates to the technical field of semiconductor devices and integrated circuits, and more specifically, to a single-transistor structure, a multi-transistor structure, and an electronic apparatus.

### BACKGROUND

More and more electronic devices are widely used in people's daily life and work with the continuous development of science and technology. Nowadays electronic devices bring great convenience and have become an indispensable tool in people's daily life and work.

Integrated circuits are centers that control the electronic devices to implement various functions. Transistors are one of the main components in the integrated circuits. An integrated circuit occupies a relatively large area when fabricated with transistors having conventional structures.

### SUMMARY

In view of the above, a single-transistor structure, a multi-transistor structure, and an electronic apparatus are provided in embodiments of the present disclosure. The technical solutions are as follows.

A single-transistor structure is provided according to an embodiment of the present disclosure. The single-transistor structure includes: a substrate; a channel, a source, and a drain, which are located at a same side of the substrate, where the channel has a first end and a second end, which are opposite to each other, along direction, the source is in electrical contact with the first end, and the drain is in electrical contact with the second end; a gate disposed between the source and the drain, where the gate wraps a part of the channel, and an insulator is sandwiched between the channel and the gate; and a channel electrode, where the channel electrode is in electrical contact with another part of the channel which is exposed from the gate, the channel electrode and the part of the channel covered by the gate overlap partially along the extension direction, and the channel electrode is isolated and insulated from the gate.

In an embodiment, the channel has multiple side surfaces, where at least one of the side surfaces is partially or totally exposed from the gate for arranging the channel electrode.

In an embodiment, the channel has a first side surface and a third side surface which are opposite to each other, and a second side surface and a fourth side surface which are opposite to each other; the gate includes at least one of a first sub-gate, a second sub-gate, a third sub-gate or a fourth sub-gate; and the first sub-gate covers at least a portion of the first side surface, the second sub-gate covers at least a portion of the second side surface, the third sub-gate covers at least a portion of the third side surface, and the fourth sub-gate covers a portion of the fourth side surface.

In an embodiment, two adjacent ones of the side surfaces are both covered by corresponding sub-gates, and the corresponding sub-gates are integrated as a whole or separated from each other.

In an embodiment, a sub-gate located on one of the side surfaces is an integral structure or includes multiple electrode blocks.

In an embodiment, the channel electrode serves as at least one of an output electrode and/or an input electrode.

In an embodiment, along a direction pointing from the first side surface to the third side surface, a thickness H₁ of the channel is greater than or equal to a thickness H₂ of the channel electrode, and the channel electrode is disposed between the first side surface and the third side surface.

In an embodiment, H₂ is less than H₁, a distance from the channel electrode to the first side surface is greater than, less than, or equal to a distance from the channel electrode to the third side surface.

In an embodiment, the channel includes a first side surface and a third side surface which are opposite to each other, and a second side surface and a fourth side surface which are opposite to each other; the first side surface faces away from the substrate, and the third side surface faces the substrate; at least a part of the third side surface is exposed from the gate; and the channel electrode is disposed in the substrate and in contact with the part of the third side surface.

In an embodiment, the single-transistor structure serves as a preset electronic component, and the preset electronic component includes at least one of a logic gate device, a memory, an optical device, an electrical device, an electronic device, an optoelectronic device, a photonic device, or a bionic/neuromorphic device; the gate serves as an input electrode of the preset electronic component; and the channel electrode serves as at least one of an output electrode of the preset electronic component or another input electrode of the preset electronic component.

In an embodiment, the gate includes multiple sub-gates which are separated from each other and serve as multiple input electrodes of the preset electronic component; and/or the channel electrode includes multiple channel sub-electrodes which are separated from each other serve as multiple output electrodes of the preset electronic component, or multiple input electrodes of the preset electronic component, or at least one input electrode and at least one output electrode of the preset electronic component.

In an embodiment, the single-transistor structure serves as a memory unit of a memory, the channel electrode form a junction capacitor with the channel to store charges, the gate and the channel electrode serve as an input control electrode of the memory unit.

In an embodiment, along the extension direction of the channel, a length L₁ of the channel is greater than a length L₂ of the channel electrode, and the channel electrode is disposed between the first end and the second end and does not directly contact with the source or the drain.

In an embodiment, L₁ ranges from 1.0×10⁻¹⁴ nm to 5.0×10⁵ nm.

In an embodiment, the single-transistor structure serves as a logic gate device, L₂<L₁/2, and the channel electrode is closer to a side of the drain.

In an embodiment, the single-transistor structure serves as a memory unit of a memory, L₂>L₁/2, and a distance from the channel electrode to the first end is equal to a distance from the channel electrode to the second end.

In an embodiment, the substrate is a semiconductor substrate or an insulating substrate; a width of the channel is uniform or non-uniform along the extension direction; and a width of the channel electrode is uniform or non-uniform along a direction pointing from an end of the channel electrode connected to the channel to an end of the channel electrode away from the channel.

In an embodiment, a length of the gate is greater than, equal to a length of the channel, along the extension direction of the channel.

In an embodiment, a length of the gate is approximately equal to a length of the channel, along the extension direction of the channel.

In an embodiment, the channel electrode includes one or more channel sub-electrodes.

In an embodiment, the channel electrode includes multiple channel sub-electrodes, and the channel sub-electrodes are disposed on a same side surface of the channel or on different side surfaces of the channel.

A multi-transistor structure is further provided according to an embodiment of the present disclosure. The multi-transistor structure includes multiple single-transistor structures, each of which is the single-transistor structure according to any foregoing embodiments.

In an embodiment, at least two of the single-transistor structures share the drain.

In an embodiment, at least two of the single-transistor structures share the source.

In an embodiment, at least two of the single-transistor structures share the channel electrode.

The at least two single-transistor structures sharing the drain have separate sources, separate channels, and separate gates.

In an embodiment, at least two of the single-transistor structures share the source while have separate drains, separate channels, and separate gates.

In an embodiment, the multiple single-transistor structures include at least a group of single-transistor structures, where the group of single-transistor structures includes two single-transistor structures of the multiple single-transistor structures, and the two single-transistor structures share the source and the drain while have separate channels and separate gates.

An electronic apparatus is further provided according to an embodiment of the present disclosure. The electronic apparatus includes the single-transistor structure and/or the multi-transistor structure according to any of the foregoing embodiments.

Thereby, the single-transistor structure, the multi-transistor structure, and the electronic apparatus are provided in technical solutions of the present disclosure. The single-transistor structure includes: the substrate, the channel, the source, and the drain, which are located at a same side of the substrate, where the channel has the first end and the second end which are opposite to each other along the extension direction, the source is in electrical contact with the first end, and the drain is in electrical contact with the second end; the gate located between the source and the drain, where the gate wraps the part of the channel, and the insulating layer is sandwiched between the channel and the gate; and the channel electrode in electrical contact with the other part of the channel which is exposed from the gate, where the channel electrode and the part of the channel covered by the gate overlap partially along the extension direction, and the channel electrode is insulated from the gate. The single-transistor structure and the multi-transistor structure herein can reduce an area occupied by an integrated circuit and improve a degree of integration.

### BRIEF DESCRIPTION OF THE DRAWINGS

For clearer illustration of the technical solutions according to embodiments of the present disclosure or present techniques, hereinafter the drawings to be applied in embodiments of the present disclosure or present techniques are briefly described. Apparently, the drawings in the following descriptions are only some embodiments of the present disclosure, and other drawings may be obtained by those skilled in the art based on the provided drawings without creative efforts.

Structures, scales, dimensions, and the like as shown in the drawings are drawn in coordination with the contents disclosed in the specification, and are intended for being understood and apprehended by a skilled person rather than putting a limitation on conditions of implementing embodiments of the present disclosure, and therefore have no actual/real significance in techniques. Any structural modification, change in proportional relationship, or adjustment in dimensions, when not affecting an effect or a purpose of embodiments of the present disclosure, shall fall within the scope covered by technical content disclosed herein.

FIG. 1 is a top view of a single-transistor structure according to an embodiment of the present disclosure.

FIG. 2 is an enlarged three-dimensional structural diagram of a part of a single-transistor structure according to an embodiment of the present disclosure.

FIG. 3 is a side view of a single-transistor structure at a side having a channel electrode according to an embodiment of the present disclosure.

FIG. 4 is a sectional view of a part of a single-transistor structure along an extension direction according to an embodiment of the present disclosure.

FIG. 5 is an enlarged three-dimensional structural diagram of a part of a single-transistor structure according to another embodiment of the present disclosure.

FIG. 6 is a side view of a single-transistor structure at a side having a channel electrode according to another embodiment of the present disclosure.

FIG. 7 is a side view of a single-transistor structure at a side having a channel electrode according to another embodiment of the present disclosure.

FIG. 8 is a sectional view of a part of a single-transistor structure along an extension direction according to another embodiment of the present disclosure.

FIG. 9 is a side view of a single-transistor structure at a side having a channel electrode according to another embodiment of the present disclosure.

FIG. 10 is a side view of a single-transistor structure at a side having a channel electrode according to another embodiment of the present disclosure.

FIG. 11 is a side view of a single-transistor structure at a side having a channel electrode according to another embodiment of the present disclosure.

FIG. 12 is a three-dimensional structural diagram of a single-transistor structure based on a FINFET technique according to an embodiment of the present disclosure.

FIG. 13 is a sectional view of a structure as shown in FIG. 12 along an extension direction of a channel according to an embodiment of the present disclosure.

FIG. 14 is a top view of a single-transistor structure having an auxiliary gate according to an embodiment of the present disclosure.

FIG. 15 is a sectional view of a structure as shown in FIG. 14 along an extension direction of a channel according to an embodiment of the present disclosure.

FIG. 16 is a top view of a single-transistor structure having an auxiliary gate according to another embodiment of the present disclosure.

FIG. 17 is a sectional view of a structure as shown in FIG. 16 along an extension direction of a channel according to an embodiment of the present disclosure.

FIG. 18 is a top view of a single-transistor structure having an auxiliary gate according to another embodiment of the present disclosure.

FIG. 19 is a top view of a single-transistor structure having an auxiliary gate according to another embodiment of the present disclosure.

FIG. 20 is a top view of a single-transistor structure according to another embodiment of the present disclosure.

FIG. 21 is a top view of a single-transistor structure according to another embodiment of the present disclosure.

FIG. 22 is a top view of a single-transistor structure according to another embodiment of the present disclosure.

FIG. 23 shows a graph of an output signal with respect to an input signal of a single-transistor structure serving as a NOT gate device according to an embodiment of the present disclosure.

FIG. 24 shows temporal waveform diagrams of an input signal and an output signal of a single-transistor NOT gate device as illustrated in FIG. 23 according to an embodiment of the present disclosure.

FIG. 25 shows the characteristic curves of a single-transistor structure serving as an AND gate according to an embodiment of the present disclosure.

FIG. 26 shows the characteristic curves of a single-transistor structure serving as an OR gate according to an embodiment of the present disclosure.

FIG. 27 shows the transfer curves of a memory according to an embodiment of the present disclosure.

FIG. 28 shows a graph of retention (or holding) time of a channel current I_{DS} according to an embodiment of the present disclosure.

FIG. 29 shows the transfer curves of a memory according to another embodiment of the present disclosure.

FIG. 30 shows a graph of device drain current and drain-source voltage of a storage array formed by single-transistor structures according to an embodiment of the present disclosure.

FIG. 31 is a top view of a multi-transistor structure according to an embodiment of the present disclosure.

FIG. 32 is a top view of a multi-transistor structure according to another embodiment of the present disclosure.

### DETAILED DESCRIPTION

Hereinafter the technical solutions of embodiments in the present disclosure are described clearly and completely in conjunction with the accompanying drawings used for the embodiments of the present disclosure. Apparently, the described embodiments are only a part of, rather than all, embodiments of the present disclosure. All other embodiments obtained by those with ordinary skill in the art based on the embodiments of the present disclosure without creative efforts shall fall within the protection scope of the present disclosure.

In order to make the above purposes, features and advantages of the present disclosure more obvious and understandable, hereinafter the present disclosure is further illustrated in detail in combination with the drawings and embodiments.

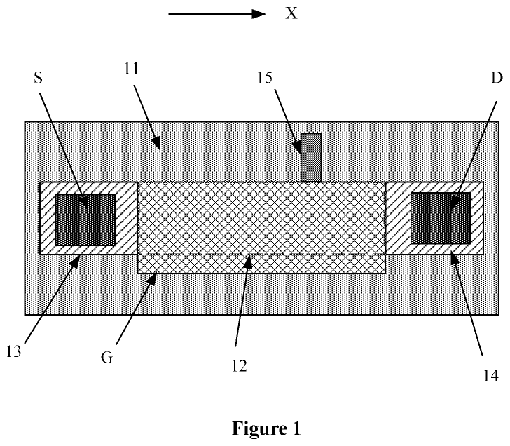

Reference is made to FIG. 1, which is a top view of a single-transistor structure according to an embodiment of the present disclosure. The single-transistor structure includes: a substrate 11, a channel 12, a source 13, a drain 14, a gate G, and a channel electrode 15.

The channel 12, the source 13 and the drain 14 are located on a same side of the substrate 11. Along an extension direction X, the channel 12 has a first end and a second end opposite to each other. The source 13 is in electrical contact with the first end, and the drain 14 is in electrical contact with the second end. The channel 12 may be p-type doped or n-type doped.

The gate G is disposed between the source 13 and the drain 14. The gate G covers a part of the channel 12. An insulating layer is sandwiched between the channel 12 and the gate G.

The channel electrode 15 is in electrical contact with another part, which is exposed from the gate G, of the channel 12. The channel electrode 15 and the part of the channel wrapped by the gate overlap partially along the extension direction X, that is, there is an overlapping region between the channel electrode 15 and a side surface, which is exposed by the gate G at such portion, in the extension direction X. The channel electrode 15 is isolated and insulated from the gate G. That is, the channel electrode 15 and the gate G are physically isolated and not in direct contact, and are further electrically insulated and not in electrical contact.

The substrate 11 may be a semiconductor substrate or an insulating substrate. In a case of the semiconductor substrate, the substrate 11 may be made of silicon, a silicon compound, germanium, a germanium compound, gallium arsenide, an optoelectric material such as carbon-based material, a bionic/neuromorphic material such as oxide material, a polymer material (with conductive agent), or other semiconductor materials. In a case of the insulating substrate, the substrate 11 may be made of ITO glass, PDMS, a polymer material, or other insulating materials.

The channel 12 may be made of an electrical material, an optical material, an electronic material, an optoelectronic material, a photonic material, for example, one or more of: a carbon-based material, a new-type carbon material, an oxide, a combination of oxides, a two-dimensional material (such as two-dimensional transitional metal sulfide), a one-dimensional material (such as oxide nanowires), a zero-dimensional material (such as carbon quantum dots), perovskite, graphene, carbon nanotubes, polymer material, unitary oxide, binary oxide, ternary oxide, quaternary oxide, other multi-nary oxides such as indium gallium zinc oxide (IGZO), indium strontium zinc oxide (ISZO), and indium strontium oxide (ISO), and indium zinc oxide (IZO), or other semiconductor materials.

The channel electrode 15 may be made of one or more materials of: a new-type carbon material, oxide, a combination of oxides, a two-dimensional material (such as two-dimensional transitional metal sulfide), oxide nanowires, perovskite, graphene, carbon nanotubes, indium gallium zinc oxide (IGZO), indium strontium oxide (ISZO), indium strontium oxide (ISO), and indium zinc oxide (IZO). The channel electrode 15 may be made of one or more materials of: unitary oxide, binary oxide, ternary oxide, quaternary oxide, other multi-nary oxides, a polymer material, an electrical material, an optical material, an electronic material, an optoelectronic material, a photonic material, such as a carbon based material, a new-type carbon material, oxide, a combination of oxides, a two-dimensional material (such as a two-dimensional transitional metal sulfide), a one-dimensional material (such as oxide nanowires), a zero-dimensional material (such as carbon quantum dots), perovskite, graphene, carbon nanotubes, indium gallium zinc oxide (IGZO), indium strontium zinc oxide (ISZO), indium strontium oxide (ISO), indium zinc oxide (IZO), a metal material or other materials.

A source electrode S may be disposed on a surface of the source 13 away from the substrate 11, and a drain D may be disposed on a surface of the drain 14 away from the substrate 11. The gate G is electrically insulated from the source S and the drain D.

In an embodiment, the channel 12 includes multiple side surfaces. At least one of the side surfaces is partially or totally exposed from the gate G, so as to arrange the channel electrode 15. The gate G may cover one or more of the side surfaces of the channel 12.

It is taken as an example that the channel 12 has a rectangular cross section in perpendicular to the extension direction X. In such case, the channel 12 has four side surfaces. The gate G may include at least one of a first sub-gate, a second sub-gate, a third sub-gate, or a fourth sub-gate. The first sub-gate covers at least a portion of the first side surface, the second sub-gate covers at least a portion of the second side surface, the third sub-gate covers at least a portion of the third side surface, and the fourth sub-gate covers at least a portion of the fourth side surface.

The gate G may be configured to cover any side surface while expose the other three side surfaces, and the channel electrode 15 may be disposed on at least one of the three exposed side surfaces exposed from the gate. Alternatively, the gate may cover any two side surfaces while expose the other two side surfaces, and the channel electrode 15 may be disposed on at least one of the two exposed side surfaces. Alternatively, the gate G may cover any three side surfaces and expose the remaining side surface, and the channel electrode 15 may be disposed on the exposed side surface. A side surface covered by a sub-gate may be partially covered by the sub-gate, and another part of such side surface may be provided with the channel electrode 15.

The sub-gate deposed on one side surface may be of an integral structure or include multiple electrode blocks. In a case that two adjacent side surfaces are both covered by sub-gates, the corresponding sub-gates may be integrated as a whole or separated from each other. The separate sub-gates may serve as multiple input electrodes.

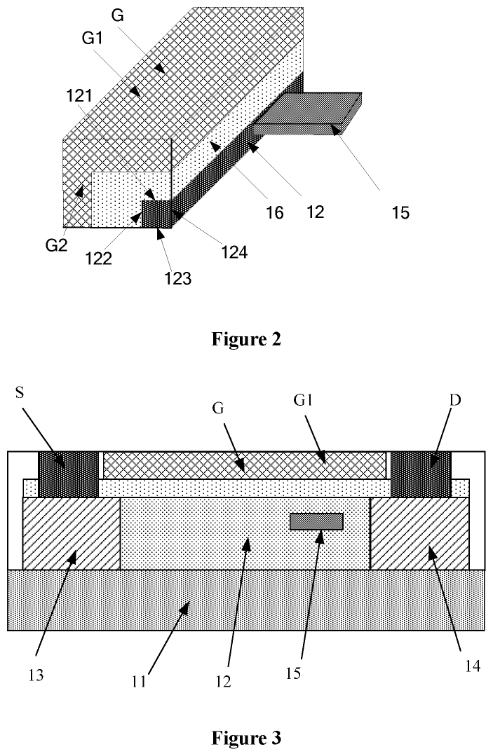

As shown in FIG. 2 and FIG. 3, FIG. 2 is an enlarged three-dimensional structural diagram of a part of a single-transistor structure according to an embodiment of the present disclosure, and FIG. 3 is a side view of a single-transistor structure at a side having a channel electrode according to an embodiment of the present disclosure. Reference is made to FIG. 1 to FIG. 3. The channel 12 has a first side surface 121 and a third side surface 123 which are opposite to each other, and a second side surface 122 and a fourth side surface 124 which are opposite to each other. The gate G includes: a first sub-gate G1 facing the first side surface 121 and a second sub-gate G2 facing the second side surface 122. At least a part of the fourth side surface 124 is exposed from the gate G, and the channel electrode 15 is in electrical contact with the part of the fourth side surface 124 exposed by the gate G. An insulating layer 16 is sandwiched between the gate G and the channel 12. The insulating layer 16 is a gate dielectric layer, which may be made of materials such as an oxide such as Al₂O₃ or a high-k material.

In the structure as shown in FIG. 2 and FIG. 3, it is illustrated that the channel electrode 15 includes one channel sub-electrode; the first side surface 121 faces away from the substrate 11, and the third side surface 123 faces toward the substrate 11 and any of the four side surfaces may face toward the substrate 11. The channel electrode 15 may include at least one channel sub-electrode, and the least one channel sub-electrode is disposed on one or more of the four side surfaces.

In the structure shown in FIG. 2, the first sub-gate G1 and the second sub-gate G2 are integrated as whole.

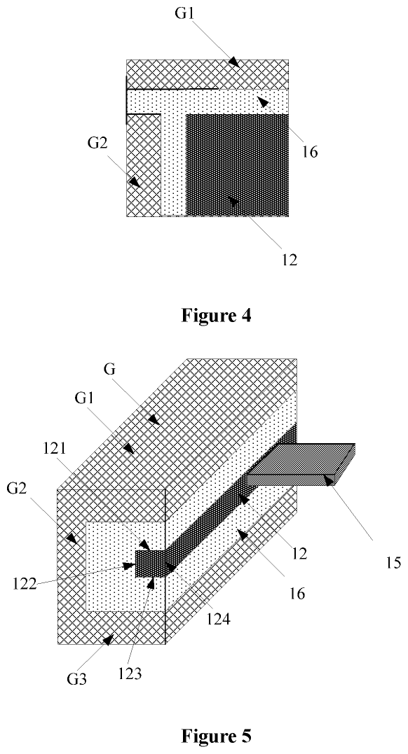

In another embodiment, the first sub-gate G1 and the second sub-gate G2 may be as shown in FIG. 4. FIG. 4 is a sectional view of a part of a single-transistor structure along an extension direction according to an embodiment of the present disclosure. The first sub-gate G1 and the second sub-gate G2 are separated from each other, and are insulated via the insulator 16.

A contact between an end of the gate G and the source 13 or the drain 14 may be non-ohmic. Reference is made to FIG. 2 and FIG. 3. Two ends of the second sub-gate G2 may be in non-ohmic contacts with the source 13 and the drain 14, respectively. For example, the channel 12 and the gate G are p-doped, the source 13 and the drain 14 are n-doped, and the two ends of the second sub-gate G2 may contact the source 13 and the drain 14, respectively. In another example, there is a gap between an end of the gate G and the source 13 or the drain 14. That is, there may be a gap between the second sub-gate G2 and the source 13 and a gap between the second sub-gate G2 and the drain 14.

It is taken as an example that the third side surface 123 faces the substrate 11 when illustrating the structure as shown in FIG. 2 and FIG. 3. In other embodiments, any of the four side surfaces of the channel may be disposed facing the substrate 11.

It is taken as an example that the channel 12 has a rectangular cross section in perpendicular to the extension direction X. The channel 12 has four side surfaces, of which the third side surface 123 is disposed facing the substrate 11, and at least a part of the third side surface 123 may be exposed from the gate G. The channel electrode 15 is disposed in the substrate 11, and contacts such part of the third side surface 123 which exposed for the gate. In such case, the gate G may cover any one, any two, or all three of the first side surface 121, the second side surface 122 and the fourth side surface 124. Herein the gate G covering a side surface indicates that the gate G covers a part or the whole of such side surface.

When disposing the channel electrode 15 in the substrate 11, a groove may be formed in the substrate 11, and then channel electrode 15 is formed in the groove. Alternatively, the channel electrode 15 may be directly formed in the substrate 11 through doping.

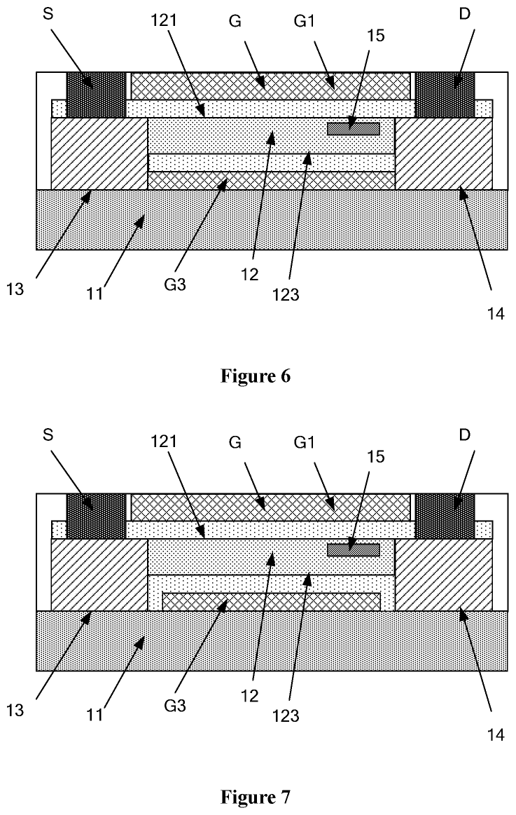

As shown in FIG. 5 and FIG. 6, FIG. 5 is an enlarged three-dimensional structural diagram of a part of a single-transistor structure according to another embodiment of the present disclosure, and FIG. 6 is a side view of a single-transistor structure at a side having a channel electrode according to another embodiment of the present disclosure. Reference is made to FIG. 1, FIG. 5, and FIG. 6. On a basis of the structure as shown in FIG. 2 and FIG. 3, the gate G further includes a third sub-gate G3 facing the third side surface 123, and the third sub-gate G3 is disposed between the channel 12 and the substrate 11.

A contact between an end of the third sub-gate G3 and the source 13 or the drain 14 may be non-ohmic. For example, the channel 12 and the gate G are p-doped, the source 13 and the drain 14 are n-doped, and the two ends of the third sub-gate G3 may contact the source 13 and the drain 14, respectively.

Reference is made to FIG. 7, which is a side view of a single-transistor structure at a side having a channel electrode according to another embodiment of the present disclosure. Different from the structure shown in FIG. 6, there are a gap between an end of the third sub-gate G3 and the source 13, and a gap between another end of the third sub-gate G3 and the drain 14. Each gap is filled with an insulating layer or a semiconductor dielectric layer.

For example, the gate G has a first sub-gate G1, a second sub-gate G2, and a third sub-gate G3. The third sub-gate G3 and the second sub-gate G2 are integrated, or the second sub-gate G2 and the first sub-gate G1 are integrated.

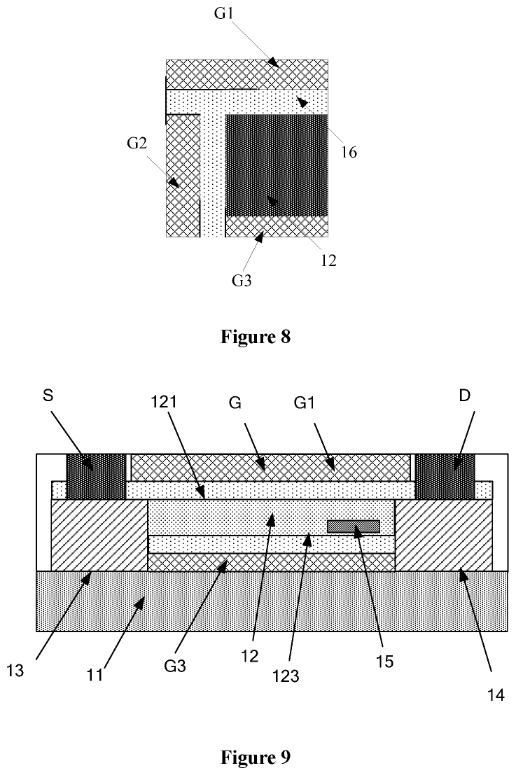

In another embodiment, the third sub-gate G3 and the second sub-gate G2 may be as shown in FIG. 8. FIG. 8 is a sectional view of a part of a single-transistor structure along an extension direction according to another embodiment of the present disclosure. The third sub-gate G3 and the second sub-gate G2 may be may be separated from each other and insulated via the insulating layer 16. In such structure, the first sub-gate G1 and the second sub-gate G2 are separate from each other. The first sub-gate G1 and the second sub-gate G2 are insulated via the insulating layer 16. Alternatively, the first sub-gate G1 and the second sub-gate G2 may be integrated as a whole.

Along a direction pointing from the first side surface 121 to the third side surface 123, a thickness of the channel 12 is H₁, and a thickness of the channel electrode 15 is H₂, and there is H₂≤H₁.

In the structure as shown in FIG. 6 and FIG. 7, there is H₂<H₁, and the channel electrode 15 is disposed closer to the first side surface 121. In such case, the channel electrode 15 may be in direct contact with the insulating layer 16 at the first side surface 121.

Reference is made to FIG. 9, which is a side view of a single-transistor structure at a side having a channel electrode according to another embodiment of the present disclosure. Different from the structure as shown in FIG. 6 or FIG. 7, the channel electrode 15 is disposed closer to the third side surface 123. In such case, the channel electrode 15 may be in directly contact with the insulating layer 16 at the third side surface 123.

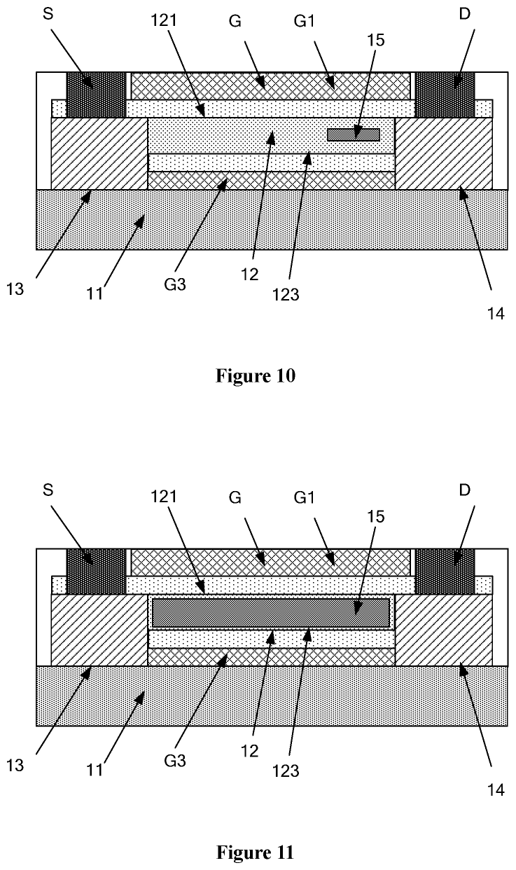

Reference is made to FIG. 10, which is a side view of a single-transistor structure at a side having a channel electrode according to another embodiment of the present disclosure. Different from the structure as shown in FIG. 6 or FIG. 7, a distance between the channel electrode 15 and the first side surface 121 is equal to a distance between the channel electrode 15 and the third side surface 123.

It is taken as an example that the gate G has the first sub-gate G1, the second sub-gate G2, and the third sub-gate G3 when illustrating the structures as shown in FIG. 6, FIG. 7, FIG. 9 and FIG. 10. In a case that a quantity of the sub-gates in the gate G is one or two, the channel electrode 15 may be also arranged with respect to the first side surface 121 and the third side surface 123 in the foregoing manners, where one sub-gate corresponds to one side surface of the channel 12.

In an embodiment, a width of the channel electrode 15 along the direction pointing from the first side surface 121 to the third side surface 123 may be set on requirement, and a position of the channel electrode 15 relative to the first side surface 121 and the third side surface 123 may be set on requirement, which are not limited thereto.

In an embodiment of the present disclosure, a length of the channel 12 along the extension direction X is L₁, a length of the channel electrode 15 along the extension direction X is L₂, and there is L₂<L₁. The channel electrode 15 is disposed between the first end and the second end of the channel 12, and has a non-zero distance to the source 13 and to the drain 14. L₁ ranges from 1.0×10⁻¹⁴ nm to 5.0×10⁵ nm.

A length L₂ of the gate G along the extension direction X of the channel 12 is greater than or equal to the length L₁ of the channel 12. Hence, a control on the channel 12 via the gate G can be maximized along the extension direction X of the channel 12.

In an embodiment, the channel electrode 15 serves as an output electrode and/or an input electrode. The channel electrode 15 may include at least one channel sub-electrode. In case of multiple channel sub-electrodes, they may be disposed on a same side surface or on different side surfaces of the channel. The multiple channel sub-electrodes may serve as multiple input electrodes, multiple output electrodes, or at least one input electrode and at least one output electrode.

In an embodiment, the single-transistor structure serves as a preset electronic component, which may include at least one of: a logic gate device, a memory, an optical device, an electrical device, an electronic device, an optoelectronic device, a photonic, or a bionic/neuromorphic device. The gate G serves as an input electrode of the preset electronic component, and the channel electrode 15 serves as an output electrode and/or another input electrode of the preset electronic component.

The gate G includes multiple sub-gates, which are separated from each other and serve as multiple input electrodes of the preset electronic component, and/or the channel electrode 15 include multiple channel sub-electrodes, which are separated from each other and serve as multiple output electrodes of the preset electronic component, multiple input electrodes of the preset electronic component, or at least one input electrode and at least one output electrode of the preset electronic component.

That is, the gate G may include multiple sub-gates which are separated from each other and serve as multiple input electrodes of the logic gate device, and the channel electrode 15 may include multiple channel sub-electrodes which are separated from each other and serve as output electrodes of the logic gate device. Hence, a multi-input-multi-output logic gate device can be implemented through one single-transistor structure, which simplifies an integrated circuit and improves a degree of integration. For the channel 12, one or more sub-gates may be configured according to a required quantity of the sub-gates in the gate G, and one or more channel sub-electrodes may be configured according to a required quantity of the channel sub-electrodes in channel electrode 15.

In a case that the single-transistor structure serves as the logic gate device, there is L₂<L₁/2, and the channel electrode 15 is disposed closer to the drain 14, as shown in FIG. 6, FIG. 7, FIG. 9 and FIG. 10. In order to facilitate extracting an output voltage, the channel electrode 15 should be disposed close to the drain 14, and the length L₂ should be as small as possible. For example, L₂ may be less than L₁/4 or L₁/10. A minimum value of L₂ needs to be determined based on manufacturing process, and a specific value of L₂ may be determined on requirement, which is not limited herein.

In an embodiment, the single-transistor structure may serve as a memory unit of a memory. The channel electrode 15 and the channel 12 form a junction capacitor to store charges, and the gate G and the channel electrode 15 serve as input control electrodes of the memory unit in the memory.

Reference is made to FIG. 11, which is a side view of a single-transistor structure at a side having a channel electrode according to another embodiment of the present disclosure. In a case that the single-transistor structure serves as a memory unit of a memory, there is L₂>L₁/2, and a distance from the channel electrode to the first end is equal to a distance from the channel electrode to the second end. In order to reach a better charge storing effect, that is, form greater junction capacitance, the length L₂ of the channel electrode 15 along the extension direction X should be as great as possible, and both a distance between an end of the channel electrode and the source 13 and a distance between another end of the channel electrode and the drain 14 should not exceed L₁/10. It is taken as an example that the gate G has three sub-gates. In a case that a quantity of sub-gates in the gate G is one or two, the channel electrode 15 may be also arranged in the manner as shown in FIG. 11. A thickness of the channel electrode 15 may be equal to a thickness of the channel 12, so that the channel electrode 15 and the channel 12 overlap completely along the direction pointing from the first side surface 121 to the third side surface 123, which increases an effective area of the junction capacitor. In such case, a larger length L₂ is preferable when ensuring insulation between the channel electrode 15 and the source and between the channel electrode 15 and the drain. A maximum value of the length L₂ depends on manufacturing process, and a specific value of the length L₂ may be determined on requirement, which is not limited herein.

In an embodiment, the channel electrode 15 of the single-transistor structure may serve as an output electrode or an input electrode of, e.g., such as the logic gate device, the memory, or other optical, electrical, electronic, optoelectronic, or photonic devices. The channel electrode 15 of the single-transistor structure may include one or more channel sub-electrodes. In a case of merely one channel sub-electrode, the channel sub-electrode may be disposed on any side surface of the channel 12. In a case of multiple channel sub-electrodes, the multiple channel sub-electrodes may be disposed on any side surface or any side surfaces of the channel 12.

Continuous development of Moore's Law requires an increasing shrinkage of an area occupied by a circuit. Conventional techniques have approaches a scale close to the molecular limit of 0.1 nm. It is difficult to follow the Moore's Law effectively through traditional techniques, and there is a need to simplify the circuits design while so that/and the disclosure here uses a one-transistor structure to replace conventional multi-transistor logic gates and multi-device memory, which can be effectively simplify the circuits. In conventional transistor structures, multiple transistors are required to implement a function of a logic gate circuit, and or multiple devices are required to implement a function of a memory. According to embodiments of the present disclosure, the single-transistor structure serves as a logic gate device, and multiple channel sub-electrodes and multiple sub-gates are configured, so as to reduce a quantity of transistors greatly, simplify a circuit structure, and improve a degree of integration. In such single-transistor structure, multiple independent sub-gates and/or multiple independent channel sub-electrodes may be arranged in correspondence to the channel 12, so that the multiple-input-multiple-output can be implemented on the single-transistor structure. The single-transistor structure can be implemented and is competent with a conventional circuit structure including multiple transistors.

The gate G covering the part of the channel 12 is well compatible with gate-all-around (GAA) techniques. Hence, in an embodiment, the single-transistor structure may be prepared through a GAA technique.

The gate G wrapping the part of the channel 12 is well compatible with fin field-effect transistor (FINFET) techniques. Hence, in an embodiment, the single-transistor structure may be fabricated through a FINFET technique. The channel electrode 15 serves as an output electrode, and the single-transistor structure is applicable to a single-transistor gate circuit, a memory, or a multi-functional device based on FINFET techniques.

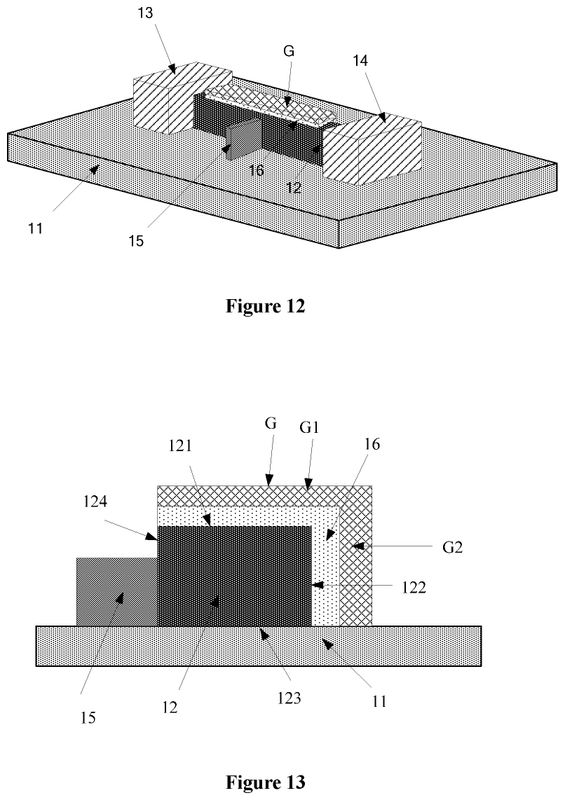

Reference is made to FIG. 12 and FIG. 13. The single-transistor structure based on the GAA may be implemented based on a FINFET technique, in order to simplify a circuit structure and reduce an area occupied by a circuit. FIG. 12 is a three-dimensional structural diagram of a single-transistor structure based on a FINFET technique according to an embodiment of the present disclosure. FIG. 13 is a sectional view of the structure as shown in FIG. 12 along an extension direction of a channel. The channel 12 serves as a fin structure of a FINFET, and the gate G covers two side surfaces of the channel 12. The gate G includes the first sub-gate G1 wrapping the first side surface 121, and the second sub-gate G2 wrapping the second side surface 122. The fourth side surface 124 of the fin structure is exposed for arranging the channel electrode 15. Alternatively, the gate covers three side surfaces of the channel 12 that are above the substrate 11, which is similar to a conventional structure, and one of the three side surfaces is partially exposed from the gate for arranging the channel electrode 15.

In another embodiment, the channel electrode 15 may be disposed within the substrate 11 and in electrical contact with the third side surface 123 of the channel. In such case, the gate G may cover at least one of the other three side surfaces. The single-transistor structure, which is based on the GAA process and implemented through the FINFET process, is applicable to a functional device that uses the channel electrode 15 for output, especially to a FINFET structure having a dimension of 28 nm or below.

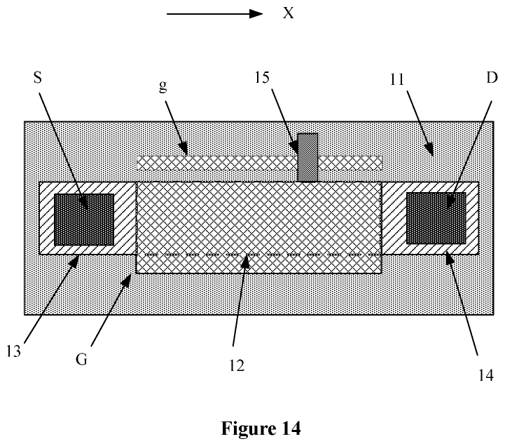

In an embodiment, the single-transistor structure may further include an auxiliary gate g. The auxiliary gate g may be arranged as shown in FIG. 14 to FIG. 21.

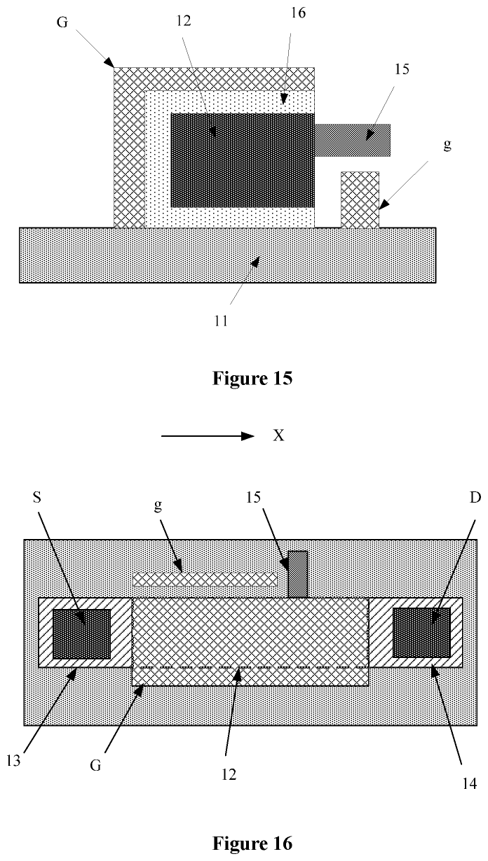

Reference is made to FIG. 14 and FIG. 15. FIG. 14 is a top view of a single-transistor structure having an auxiliary gate according to an embodiment of the present disclosure. FIG. 15 is a sectional view of the structure in FIG. 14 along an extension direction. On a basis of previous embodiments, the structure as shown in FIG. 14 and FIG. 15 further includes an auxiliary gate g. The auxiliary gate g and the channel electrode 15 are disposed on a same side of the channel 12. There is a gap between the auxiliary gate g and the channel 12, and the gap may be filled with an insulating layer or a semiconductor material. There is a gap between the auxiliary gate g and the channel electrode 15, and the gap may be filled with an insulating layer or a semiconductor material. In this structure, the channel electrode 15 is located between two ends of the auxiliary gate g along the extension direction X. Along the direction pointing from the first side surface 121 to the third side surface 123, the auxiliary gate g is located between the substrate 11 and the channel electrode 15, and is separated from the channel electrode 15 via a gap.

In the structure as shown in FIG. 14, the auxiliary gate g does not overlap with the source 13 or the drain 14 along the extension direction X of the channel 12. In another embodiment, the auxiliary gate g may overlap with the source 13 and/or the drain 14.

Reference is made to FIG. 16, which is a top view of a single-transistor structure having an auxiliary gate according to another embodiment of the present disclosure. In this structure, along the extension direction X, the channel electrode 15 is disposed closer to the drain 14, and the auxiliary gate g is disposed between the source 13 and the channel electrode 15. When viewed along the direction pointing from the first side surface 121 to the third side surface 123, the channel electrode 15 and the auxiliary gate g do no overlap and there is a gap between the two. Hence, a relationship between heights above the substrate 11, of the channel electrode 15 and the auxiliary gate g, may be arbitrarily configured. The channel electrode 15 may be higher than the auxiliary gate g, as shown in FIG. 15. Alternatively, the auxiliary gate g may be higher than the channel electrode 15, or the channel electrode 15 and the auxiliary gate g may be flush with each other. The auxiliary gate g may alternatively be dispose at a side of the channel electrode 15 close to the drain 14.

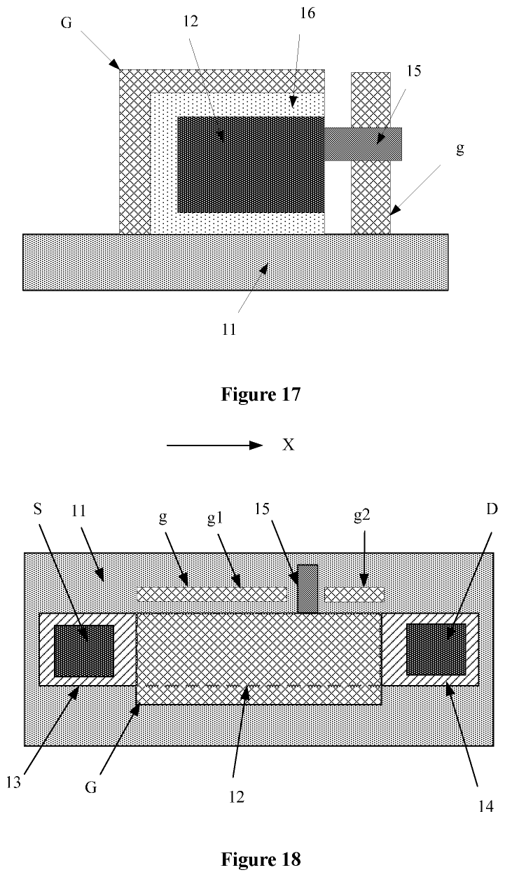

Reference is made to FIG. 17, which is a sectional view of the structure as shown in FIG. 16 along an extension direction of the channel 12. In this structure, the auxiliary gate g is higher than the channel electrode 15.

Reference is made to FIG. 18, which is a top view of a single-transistor structure having an auxiliary gate according to another embodiment of the present disclosure. Based on the structure as shown in FIG. 16, the auxiliary gate g in FIG. 18 has a first auxiliary sub-gate g1 and a second auxiliary sub-gate g2. Along the extension direction X of the channel 12, the first auxiliary sub-gate g1 and the second auxiliary sub-gate g2 are disposed on two sides of the channel electrode 15, respectively. Lengths of the two auxiliary sub-gates may be configured on requirement. In this structure, along the extension direction X of the channel 12, the first auxiliary sub-gate g1 does not overlap with the source 13, and the second auxiliary sub-gate g2 does not overlap with the drain 14. That is, the auxiliary gate g does not influence the source 13 and the drain 14.

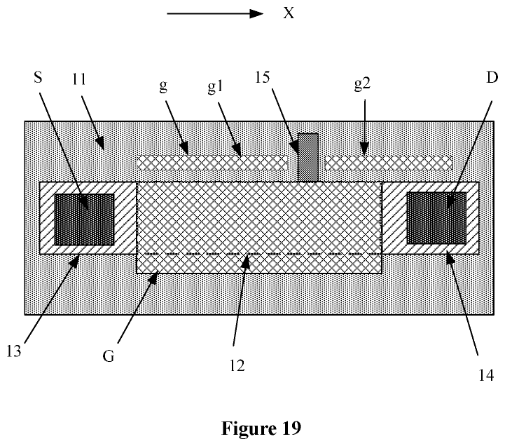

Reference is made to FIG. 19, which is a top view of a single-transistor structure having an auxiliary gate according to another embodiment of the present disclosure. In this structure, along the extension direction X of the channel 12, the second auxiliary sub-gate g2 overlaps the drain 14, and therefore the second auxiliary sub-gate g2 may affect the drain 14. In another implementation, the first auxiliary sub-gate g1 may overlap the source 13, so that the first auxiliary sub-gate g1 may affect the source 13.

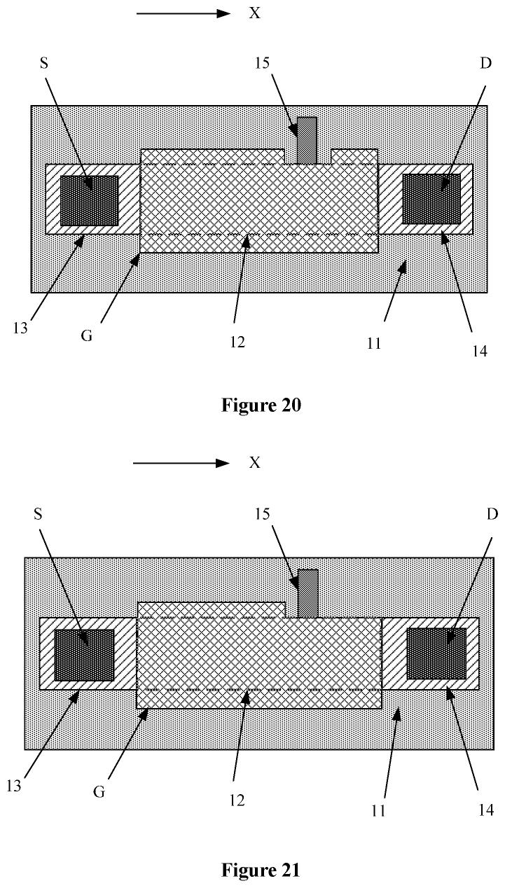

In the foregoing embodiments, it is taken as an example that a sub-gate covers the whole side surface at which the sub-gate is located. Alternatively, the sub-gate may be configured to cover a part of the side surface of the channel, as shown in FIGS. 20 and 21.

Reference is made to FIG. 20, which is a top view of a single-transistor structure according to another embodiment of the present disclosure. On a basis of the forgoing embodiments, the gate G as shown in FIG. 20 may cover three side surfaces. For example, the channel 12 includes the first side surface and the third side surface which are opposite to each other, and the second side surface and the fourth side surface which are opposite to each other. The third side surface facing the substrate 11. The gate G covers the first side surface, the second side surface, and the fourth side surface. The gate G may cover the whole first side surface and the whole second side surface, and cover only a part of the fourth side surface, so as to expose the other part of the fourth side surface. The channel electrode 15 may be disposed on the exposed part from the gate of the fourth side surface. There may be no gate on the third side surface facing the substrate 11.

As shown in FIG. 20, along the extension direction X of the channel 12, a window is formed in the sub-gate located on the fourth side surface, which exposes a part of the fourth side surface. Two parts of the sub-gate is located at two sides, respectively, of the window, and such two parts may be separated via the window. In such case, the window traverses the fourth side surface, or the window may be configured to dissect only a portion of the sub-gate on the fourth side surface. In the latter case, the two parts of the sub-gates at two sides of the window are still physically connected.

Reference is made to FIG. 21, which is a top view of a single-transistor structure according to another embodiment of the present disclosure. Different from the structure as shown in FIG. 20, along the extension direction X of the channel 12, the sub-gate on the fourth side surface is disposed on only one side of the channel electrode 15.

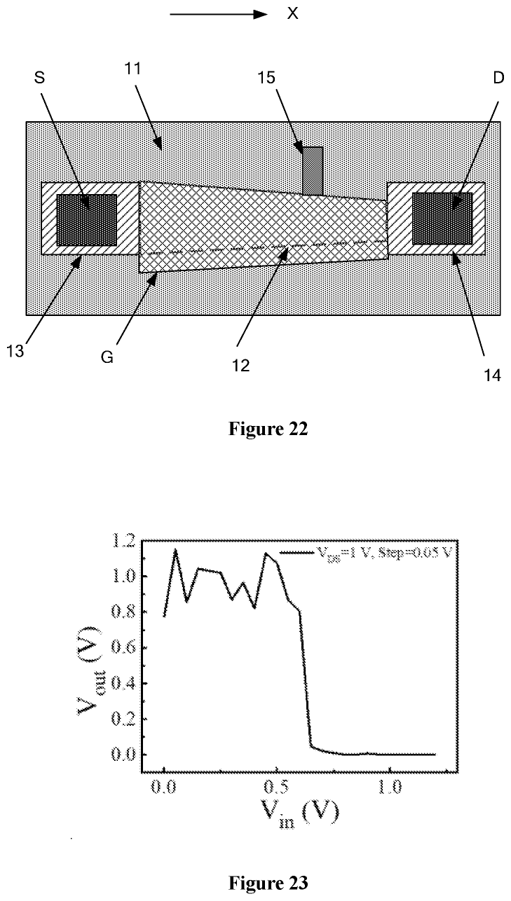

In this embodiment, a width of the channel 12 is uniform. In another embodiment, the width of the channel 12 may be non-uniform along the extension direction X, as shown in FIG. 22. For example, the width of the channel 12 may be subject to gradual variation along the extension direction X.

Reference is made to FIG. 22, which is a top view of a single-transistor structure according to another embodiment of the present disclosure. Different from the structure as shown in FIG. 1, the width of the channel 12 increases gradually along the direction pointing from the drain 14 to the source 13. Hence, the channel 12 has a larger width at an end close to the source 13, which facilitates adjusting an output voltage, power consumption, and delay.

In another example, the width of the channel 12 may decrease gradually along the direction pointing the drain 14 to the source 13.

In the above embodiments, a width of the channel electrode 15 may be uniform or non-uniform along the extension direction X of the channel 12. For example, the width of the channel electrode 15 may increase or decrease gradually along an extension direction of the channel electrode 15. The extension direction of the channel electrode 15 refers to a direction pointing from an end of the channel electrode 15, which is connected to the channel 12, to another end of the channel electrode 15, which is away from the channel 12.

It is taken as an example that the width of the channel electrode is uniform when illustrating and describing the foregoing embodiments of the present disclosure. In other embodiments, the width of the channel electrode may be non-uniform, that is, change gradually or irregularly along its extension direction.

It is taken as an example that the channel electrode contacts the channel at a surface of the channel when illustrating and describing the foregoing embodiments of the present disclosure. In other embodiments, an end of the channel electrode contacting the channel may protrude into the channel.

A shape and a dimension of the channel electrode 15 are adjustable, and are not limited herein. A cross-section of the channel electrode 15 in perpendicular to the extension direction X may be a rectangular as shown in the foregoing embodiments of the present disclosure. In other embodiments, the cross section may be circular or wedge-shaped, or have other geometric shapes.

Effects of the single-transistor structures in the embodiments of the present disclosure are illustrated in combination with test data.

### I. As a NOT Gate

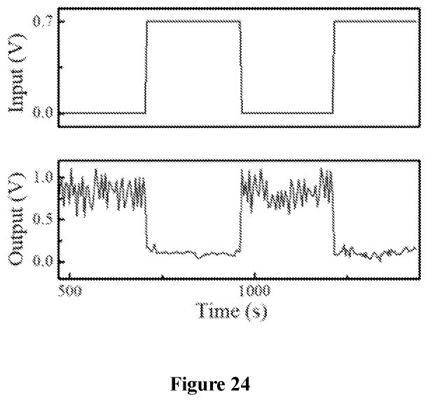

The single-transistor structure herein may serve as a NOT gate device. The gate serves as an input electrode supplying an input signal Vin, and the channel electrode serves as an output electrode providing an output signal Vout. Reference is made to FIG. 23 and FIG. 24. FIG. 23 shows a graph of an input signal with respect to an output signal of a single-transistor structure serving as a NOT gate device, and FIG. 24 shows temporal waveform diagrams of an input signal and an output signal of the NOT gate device as shown in FIG. 23. A voltage less than 0.7V is considered to be logic 0, and a voltage greater than or equal to 0.7V is considered to be logic 1, without a potential on the substrate. In such case, the single-transistor structure can serve as the NOT gate device and presents good NOT characteristics.

### II. As a Two-Input Logic Device

The single-transistor structure herein may serve as a two-input logic device, such as a NAND gate device, an OR gate device, an AND gate device, or the like.

The gate may be provided with two independent sub-gates which serve as input electrodes. The channel electrode serves as an output electrode. Alternatively, the auxiliary gate may serve as an input electrode, and the gate covering the channel serves as another input electrode.

The single-transistor structure may serve as a NAND gate, and a source-drain voltage V_{DS} is 0.9V without a potential on the substrate. In such case, the input signals and the output signal may be as shown in Table 1.

TABLE 1

| Input signal 1 | Input signal 2 | Output signal 1 |
|---|---|---|
| 0.1 V | 0 V | 0.8565952 V |
| 0.9 V | 0 V | 0.9099755 V |
| 0.1 V | 0.5 V | 0.7420985 V |
| 0.9 V | 0.5 V | 0.1618004 V |

If a voltage less than 0.5V is considered/set to be logic 0, and a voltage greater than or equal to 0.5V is considered set to be logic 1. It can be seen from Table 1 that the single-transistor structure can serve as the NAND gate and presents good NAND characteristics.

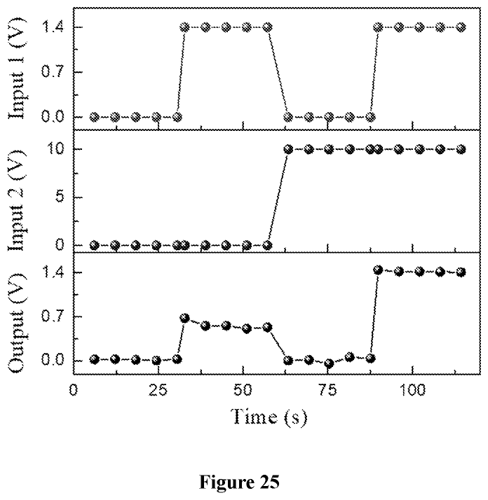

The single-transistor structure may serve as an AND gate. A source-drain voltage V_{DS} is 6V with the substrate having a potential same as the source. In such case, the input signals and the output signal may be as shown in Table 2 and FIG. 25.

TABLE 2

| Input signal 1 | Input signal 2 | Output signal 1 |
|---|---|---|
| 0 V | 0 V | 0.18705 V |
| 1.4 V | 0 V | 0.505729 V |
| 0 V | 10 V | 0.26241 V |
| 1.4 V | 10 V | 1.3994 V |

If a voltage less than 0.7V is set to be a logic 0, and a voltage greater than or equal to 0.7V is considered to be a logic 1. FIG. 25 shows the characteristic curves of a single-transistor structure serving as an AND gate according to an embodiment of the present disclosure. It can be seen from Table 2 and FIG. 25 that the single-transistor structure can serve as the AND gate and presents good AND characteristics.

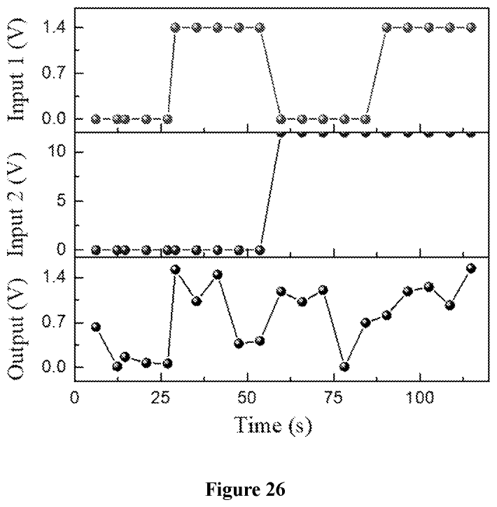

The single-transistor structure may serve as an OR gate. A source-drain voltage V_{DS} is 6V with the substrate has a potential same as the source. In such case, the input signals and the output signal are as shown in Table 3 and FIG. 26.

TABLE 3

| Input signal 1 | Input signal 2 | Output signal 1 |
|---|---|---|
| 0 V | 0 V | 0.160554 V |
| 1.4 V | 0 V | 1.0308 V |
| 0 V | 12 V | 1.019 V |
| 1.4 V | 12 V | 1.1847 V |

A voltage less than 0.7V is considered to be a logic 0, and a voltage greater than or equal to 0.7V is considered to be a logic 1. FIG. 26 shows the characteristic curves of a single-transistor structure serving as an OR gate according to an embodiment of the present disclosure. It can be seen from Table 3 and FIG. 26 that the single-transistor structure can serve as the OR gate and presents good OR characteristics.

### III. As a Memory Unit

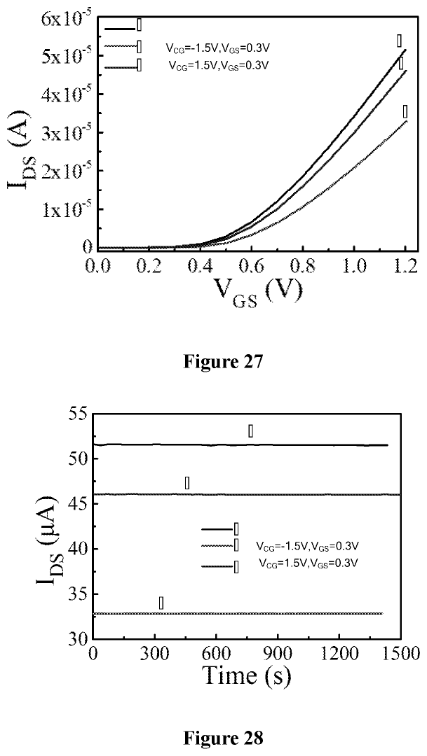

Reference is made to FIG. 27 and FIG. 28. FIG. 27 shows the transfer curves of a memory according to an embodiment of the present disclosure. Curve \textcircled{1} is a transfer curve of a original memory, and curve \textcircled{2} and curve \textcircled{3} are the transfer curves of a memory in which the single-transistor structure according to embodiments of the present disclosure serve as memory units. As shown in FIG. 27, a channel current I_{DS} increases with an increasing gate-voltage V_{GS}. FIG. 28 shows a graph of retention (holding) time of a channel current I_{DS}. As shown in FIG. 28, the channel current of the single-transistor structure serving as the memory unit can hold more than 1200 seconds, which meets a requirement on storage performances of memory units in the memory.

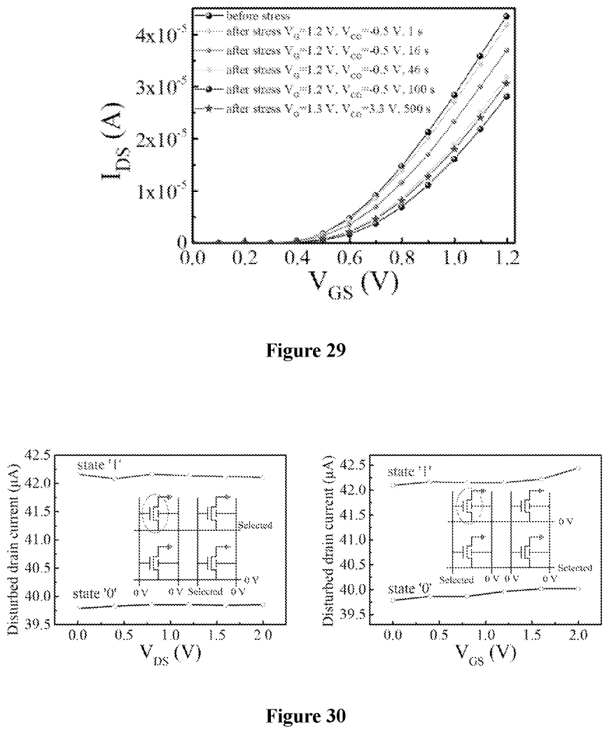

Reference is made to FIG. 29, which shows the transfer curves of a memory according to another embodiment of the present disclosure. The topmost curve in FIG. 29 is a transfer curve of a conventional memory, and the other curves are transfer curves of a memory using the single-transistor structure as a memory unit according to embodiments of the present disclosure. As shown in FIG. 29, in a case that the single-transistor structure serves as the memory unit, an on-off ratio of the memory is still adjustable by programming.

Reference is made to FIG. 30, which a graph of device drain current and drain-to-source voltage of a memory array formed by single-transistor structures according to an embodiment of the present disclosure. As shown in FIG. 30, a device drain current at a half-selected device is disturbed via a bit line BL and a word line WL. Even when a voltage is 0.5V higher than the writing threshold, no obvious half-select disturb is observed on the bit line BL and the word line WL. Hence, the storage array fabricated from the single-transistor structures herein can achieve stable circuit performances.

The single-transistor structure is not limited to application in the logic gate device or the memory. The single-transistor structure may be applied to a bionic/neuromorphic device, for example, an integrated circuit serving as a bionic/neuromorphic device, and achieves a bionic/neuromorphic effect.

A position of the channel electrode 15 is not limited to the foregoing embodiments, and may be configured on the channel 12 on requirement. A quantity of channel sub-electrodes in the channel electrode 15 is not limited to one, and may be greater than one. The channel electrode 15 may serve as an input or output electrode of the logic gate device, the bionic/neuromorphic device, an optical device, an electrical device, an electronic device, an optoelectronic device, a photonic, or the like.

Based on the above embodiments, a multi-transistor structure is further provided according to another embodiment of the present disclosure. The multi-transistor structure includes multiple single-transistor structures, each of which is the single-transistor structure according to any foregoing embodiment. The multiple single-transistor structures are disposed on a same side of the same substrate.

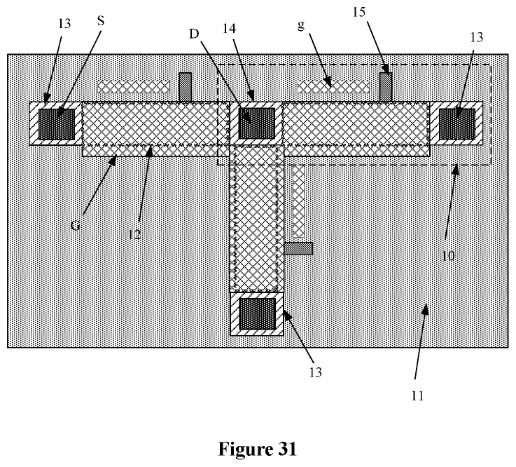

Reference is made to FIG. 31, which is a top view of a multi-transistor structure according to an embodiment of the present disclosure. The multi-transistor structure includes multiple single-transistor structures 10, each of which is the single-transistor structure according to any foregoing embodiment.

When there are the multiple single-transistor structures 10, at least two single-transistor structures 10 may share the drain 14. Each of the single-transistor structures 10 sharing the drain 14 has the separate source 13, the separate channel 12, and the separate gate G, and may have the separate channel electrode 15. In the structure as shown in FIG. 31, there are three single-transistor structures 10 which share the drain 14.

The channels 12 are indicated by thick dashed lines, and a single-transistor structure is indicated by a thin dashed line.

When there are the multiple single-transistor structures 10, at least two of the single-transistor structures 10 may share the source 13. Each of the single-transistor structures sharing the source 13 has the separate drain 14, the separate channel 12, and the separate gate G, and may have the separate channel electrode 15. An implementation principle for such structure is the same as that for the structure as shown in FIG. 31, and is not repeated herein.

When there are the multiple single-transistor structures 10, different single-transistor structures 10 may have identical or different structures. Each of the single-transistor structures may be implemented according to any foregoing embodiment.

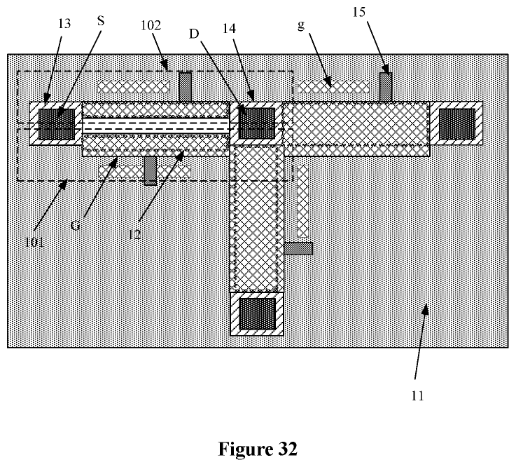

Reference is made to FIG. 32, which is a top view of a multi-transistor structure according to another embodiment of the present disclosure. The multi-transistor structure 10 includes at least one group of single-transistor structures. The group of single-transistor structures has two single-transistor structures 10 which share the source 13 and the drain 14. Each of the two single-transistor structures 10 has the separate channel 12 and the separate gate G, and may have the separate channel electrode 15. As shown in FIG. 32, the group of single-transistor structures includes a first single-transistor structure 101 and a second single-transistor structure 102. The first single-transistor structure 101 and the second single-transistor structure 102 share the source 13 and the drain 14, while each has the separate channel 12, the separate gate G, and the separate channel electrode 15.

The single-transistor structure in the multi-transistor structure according to embodiments of the present disclosure may be implemented according to any foregoing embodiment, and details are not repeated herein.

Based on the above embodiment, an electronic apparatus is further provided according to another embodiment of the present disclosure. The electronic apparatus includes the single-transistor structure and/or the multi-transistor structure according to any foregoing embodiment.

The electronic apparatus may be at least one of: an integrated circuit having a logic gate device, an integrated circuit having a memory, an integrated circuit having a bionic/neuromorphic device, an integrated circuit having a sensor, or an integrated circuit having an optical device, an electrical device, an electronic device, an optoelectronic device, a photonic.

The electronic apparatus using the single-transistor structure and/or the multi-transistor structure is capable to reduce an area occupied by the integrated circuit and improve a degree of integration.

The single-transistor structure and multi-transistor structure described herein are applicable, but not limited, to all circuits such as memory units, logic gates, optical devices, electrical devices, electronic devices, optoelectronic devices, photonic devices, sensors, bionic artificial synaptic devices, or other bionic/neuromorphic devices.

Herein the embodiments are described in a progressive, or parallel, or a combination of progressive and parallel manner. Each of the embodiments focuses on differences from other embodiments, and the same and similar parts of the embodiments can be referred to each other. Description of the electronic apparatuses disclosed in the embodiments is simple, as the electronic apparatus corresponds to the transistor structure disclosed in the embodiments. Reference may be made to corresponding description of the transistor structure for details of the electronic apparatus.

It should be understood that in the description of the present disclosure, orientations or positional relationships indicated by the terms “upper”, “lower”, “top”, “bottom”, “inside”, “outside”, and the like, are based on the drawings. These terms are merely intended for facilitating describing the present disclosure and simplifying the description, rather than indicating or implying that apparatus, or elements defined by the terms must comply with the designated orientation, or must be constructed and operated according to the designated orientation. Therefore, such terms should not be construed as a limitation to the present disclosure. When a component is considered to be “connected” to another component, the component may be connected to another component directly or through an intermediate element.

It should be noted that the relationship terminologies such as first, second or the like are used herein to distinguish one entity or operation from another, rather than to necessitate or imply an actual relationship or order among the entities or operations. Furthermore, terms “include”, “comprise” or any other variants are intended to cover a non-exclusive inclusion. Therefore, an article or device including a series of elements is not necessarily limited to those expressly listed elements, but may include other elements not expressly listed or inherent to the article, or device. Unless expressively limited otherwise, a statement “comprising (including) one . . . ” does not exclude existence of another similar element in the article or device.

The above description of the disclosed embodiments enables those skilled in the art to implement or use the present disclosure. Various modifications to the embodiments are apparent to those skilled in the art. The general principles defined herein can be implemented in other embodiments, without departing from the spirit or scope of the present disclosure. Therefore, the present disclosure is not limited to the embodiments illustrated herein, but conforms to the widest scope consistent with the principles and novel features disclosed herein.

1. A single-transistor structure, comprising:
a substrate;
a channel, a source, and a drain, which are located at a same side of the substrate, wherein: the channel extends along an extension direction, and has a first end and a second end, which are opposite to each other, along the extension direction, the source is in electrical contact with the first end, and the drain is in electrical contact with the second end;
a gate disposed between the source and the drain, wherein the gate covers a part of the channel, and an insulating layer is sandwiched between the channel and the gate; and
a channel electrode, wherein the channel electrode is in electrical contact with another part of the channel which is exposed from the gate, the channel electrode and the part of the channel covered by the gate overlap partially along the extension direction, and the channel electrode is isolated and insulated from the gate.

2. The single-transistor structure according to claim 1, wherein the channel has a plurality of side surfaces, wherein at least one side surface of the plurality of side surfaces is partially or totally exposed from the gate for arranging the channel electrode.

3. The single-transistor structure according to claim 2, wherein:
the plurality of side surfaces comprises a first side surface and a third side surface which are opposite to each other, and a second side surface and a fourth side surface which are opposite to each other;
the gate comprises at least one of a first sub-gate, a second sub-gate, a third sub-gate or a fourth sub-gate; and
the first sub-gate covers at least a portion of the first side surface, the second sub-gate covers at least a portion of the second side surface, the third sub-gate covers at least a portion of the third side surface, and the fourth sub-gate at least covers a portion of the fourth side surface.

4. The single-transistor structure according to claim 2, wherein two adjacent side surfaces of the plurality of side surfaces are both covered by corresponding sub-gates, and the corresponding sub-gates are integrated as a whole or separated from each other.

5. The single-transistor structure according to claim 3, wherein a sub-gate located on one of the plurality of side surfaces is an integral structure or comprises a plurality of electrode blocks.

6. The single-transistor structure according to claim 1, wherein the channel electrode serves as at least one of an output electrode or an input electrode.

7. The single-transistor structure according to claim 3, wherein along a direction pointing from the first side surface to the third side surface,
a thickness H₁ of the channel is greater than or equal to a thickness H₂ of the channel electrode, and the channel electrode is disposed between the first side surface and the third side surface.

8. The single-transistor structure according to claim 7, wherein H₂ is less than H₁, a distance from the channel electrode to the first side surface is greater than, less than, or equal to a distance from the channel electrode to the third side surface.

9. The single-transistor structure according to claim 3, wherein:
the first side surface faces away from the substrate, and the third side surface faces the substrate;
at least a part of the third side surface is exposed from the third sub-gate; and
the channel electrode is disposed in the substrate and in contact with the part of the third side surface.

10. The single-transistor structure according to claim 1, wherein:
the single-transistor structure serves as a preset electronic component, which is at least one of a logic gate device, a memory, an optical device, an electrical device, an electronic device, an optoelectronic device, a photonic device, an electronic device, an optoelectronic device, or a bionic/neuromorphic device;
the gate serves as an input electrode of the preset electronic component; and
the channel electrode serves as at least one of an output electrode of the preset electronic component or another input electrode of the preset electronic component.

11. The single-transistor structure according to claim 10, wherein
the gate comprises a plurality of separated sub-gates, which serves as a plurality of input electrodes of the preset electronic component; and/or
the channel electrode comprise a plurality of separated channel sub-electrodes, which serves as:
a plurality of output electrodes of the preset electronic component,
a plurality of input electrodes of the preset electronic component, or
at least one input electrode of the preset electronic component and at least one output electrode of the preset electronic component.

12. The single-transistor structure according to claim 1, wherein:
the single-transistor structure serves as a memory unit of a memory,
the channel electrode and the channel form a junction capacitor to store charges, and
the gate and the channel electrode serve as an input control electrode of the memory unit.

13. The single-transistor structure according to claim 1, wherein along the extension direction,
a length L₁ of the channel is greater than a length L₂ of the channel electrode, and the channel electrode is disposed between the first end and the second end and does not directly contact the source or the drain.

14. (canceled)

15. The single-transistor structure according to claim 13, wherein:
the single-transistor structure serves as a logic gate device, L₂<L₁/2, and the channel electrode is closer to the drain than to the source.

16. The single-transistor structure according to claim 13, wherein:
the single-transistor structure serves as a memory unit of a memory, L₂>L₁/2, and a distance from the channel electrode to the first end is equal to a distance from the channel electrode to the second end

17. The single-transistor structure according to claim 1, wherein:
a width of the channel is uniform or non-uniform along the extension direction; or
a width of the channel electrode is uniform or non-uniform along a direction pointing from an end of the channel electrode connected to the channel to an end of the channel electrode away from the channel.

18. The single-transistor structure according to claim 1, wherein a length of the gate is greater than or equal to a length of the channel, along the extension direction of the channel.

19. The single-transistor structure according to claim 1, wherein the channel electrode comprises one or more channel sub-electrodes.

20. The single-transistor structure according to claim 1 claim 19, wherein the channel electrode has a plurality of channel sub-electrodes, and the channel sub-electrodes are disposed on a same side surface of the channel or on different side surfaces of the channel.

21. A multi-transistor structure, comprising a plurality of single-transistor structures, each of which is the single transistor structure according to claim 1.

22. The multi-transistor structure according to claim 21, wherein at least two single-transistors of the plurality of single-transistor structures share the drain, and
the at least two single-transistor structures have separate sources, separate channels, separate gates, and separate channel electrodes.

23. The multi-transistor structure according to claim 21, wherein at least two single-transistors of the plurality of single-transistor structures share the source, and
the at least two single-transistor structures have separate drains, separate channels, and separate gates.

24. The multi-transistor structure according to claim 21, wherein at least two single-transistors of the plurality of single-transistor structures share the channel electrode, and
the at least two single-transistor structures have separate sources, separate drains, and separate gates.

25. The multi-transistor structure according to claim 21, wherein:
the plurality of single-transistor structures comprises at least a group of single-transistor structures, and the group of single-transistor structures comprises two single-transistor structures of the plurality single-transistor structures; and
the two single-transistor structures share the source and the drain while have separate channels and separate gates.

26. An electronic apparatus, which is a circuit or a transistor array, comprising:
the single-transistor structure according to claim 1.

27. An electronic apparatus, which is a circuit or a transistor array, comprising:
the multi-transistor structure according to claim 21.

28. The single-transistor structure according to claim 1, wherein the channel electrode has a plurality of channel sub-electrodes, and the channel sub-electrodes are disposed on a same side surface of the channel.

29. The single-transistor structure according to claim 1, wherein the channel electrode is made of an optical material, an electrical material, an electronic material, an optoelectronic material, or a photonic material.

30. The single-transistor structure according to claim 1, wherein the gate covers the part of the channel.

31. The single-transistor structure according to claim 1, wherein the channel electrode is the material which could form a junction with the channel or which could extract a fixed voltage from the channel.

32. The single-transistor structure according to claim 1, wherein the channel electrode could be formed via doping.

33. The single-transistor structure according to claim 1, wherein the channel electrode is the material which could form a junction with the channel or which could extract a fixed voltage from the channel, and the channel electrode could be formed via doping.
